(19) United States
(12) Patent Application Publication
(10) Pub. No.: US 2013/0224960 A1
(43) Pub. Date: Aug. 29, 2013

(54) METHODS FOR ETCHING OXIDE LAYERS USING PROCESS GAS PULSING

(71) Applicants: Jairaj Payyapilly, Sunnyvale, CA (US); Jong Mun Kim, San Jose, CA (US); Kenny Doan, San Jose, CA (US); Li Ling, San Jose, CA (US)

(72) Inventors: Jairaj Payyapilly, Sunnyvale, CA (US); Jong Mun Kim, San Jose, CA (US); Kenny Doan, San Jose, CA (US); Li Ling, San Jose, CA (US)

(73) Assignee: APPLIED MATERIALS, INC., Santa Clara, CA (US)

(21) Appl. No.: 13/882,272

(22) PCT Filed: Oct. 27, 2011
(86) PCT No.: PCT/US11/58003

§ 371 Date: May 2, 2013

Related U.S. Application Data
(60) Provisional application No. 61/407,983, filed on Oct. 29, 2010.

(51) Int. Cl. H01L 21/3065

(52) U.S. Cl. CPC H01L 21/3065
USPC 438/714

(57) ABSTRACT

Methods for etching an oxide layer disposed on a substrate through a patterned layer defining one or more features to be etched into the oxide layer are provided herein. In some embodiments, a method for etching an oxide layer disposed on a substrate through a patterned layer defining one or more features to be etched into the oxide layer may include: etching the oxide layer through the patterned layer using a process gas comprising a polymer forming gas and an oxygen containing gas to form the one or more features in the oxide layer; and pulsing at least one of the polymer forming gas or the oxygen containing gas for at least a portion of etching the oxide layer to control a dimension of the one or more features.

### FIELD

Embodiments of the present invention generally relate to semiconductor substrate processing.

### BACKGROUND

As device nodes get smaller (for example, approaching dimensions of about 40 nm or less), manufacturing challenges may arise. For example, the inventors have observed that in the fabrication of high aspect ratio features, conventional oxide layer etching processes display poor etch selectivity and an imbalance with respect to an etch rate and polymer formation, which may result in a clogged feature opening, reduced etch rates for smaller features (sometimes referred to as Aspect Ratio Dependant Etch, or ARDE) and undesired profile shapes, for example, bowing of the feature sidewall or other undesired critical dimensions.

Thus, the inventors have provided improved methods etching oxide layers.

### SUMMARY

Methods for etching an oxide layer disposed on a substrate through a patterned layer defining one or more features to be etched into the oxide layer are provided herein. In some embodiments, a method for etching an oxide layer disposed on a substrate through a patterned layer defining one or more features to be etched into the oxide layer may include: etching the oxide layer through the patterned layer using a process gas comprising a polymer forming gas and an oxygen containing gas to form the one or more features in the oxide layer; and pulsing at least one of the polymer forming gas or the oxygen containing gas for at least a portion of etching the oxide layer to control a dimension of the one or more features. In some embodiments, one or more other parameters may be pulsed as well, such as RF power (e.g., source and/or bias), the electric field, or the component temperatures (e.g., cathode, showerhead, or chamber body).

In some embodiments, a computer readable medium may be provided having instructions stored thereon that, when executed, cause a method, for etching an oxide layer disposed on a substrate through a patterned layer defining one or more features to be etched into the oxide layer, to be performed in a process chamber. The method may include any of the methods as described herein.

Other and further embodiments of the present invention are described below.

### BRIEF DESCRIPTION OF THE DRAWINGS

Embodiments of the present invention, briefly summarized above and discussed in greater detail below, can be understood by reference to the illustrative embodiments of the invention depicted in the appended drawings. It is to be noted, however, that the appended drawings illustrate only typical embodiments of this invention and are therefore not to be considered limiting of its scope, for the invention may admit to other equally effective embodiments.

FIG. 1 is a flow diagram of a method for etching an oxide layer in accordance with some embodiments of the present invention.

FIGS. 2A-C are illustrative cross-sectional views of a substrate during different stages of the method of FIG. 1 in accordance with some embodiments of the present invention.

FIG. 3 depicts an etch reactor suitable for performing portions of the present invention.

FIG. 4 is a graph depicting pulsing of one or more process gases in accordance with some embodiments of the present invention.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

Embodiments of the present invention provide methods for etching an oxide layer disposed on a substrate. In some embodiments, the inventive methods may advantageously provide improved control over the critical dimensions of features formed in the oxide layer. Embodiments of the inventive process may further advantageously provide flexibility in control over one or more of the feature profile, etch rate, and etch selectivity with respect to the oxide layer and other layers of the substrate. Although not limiting of the scope of application of the inventive methods disclosed herein, the inventive methods have been shown to be particularly effective for the fabrication of high aspect ratio features to be used in applications such as Flash and DRAM devices.

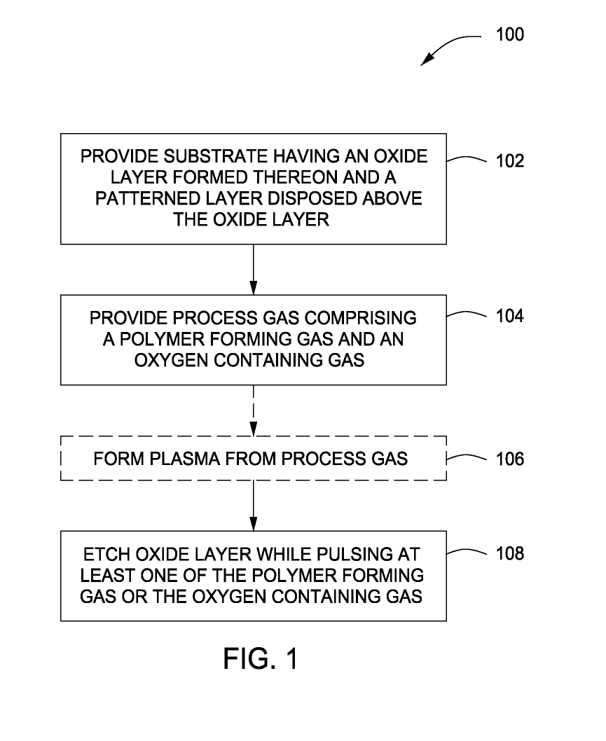

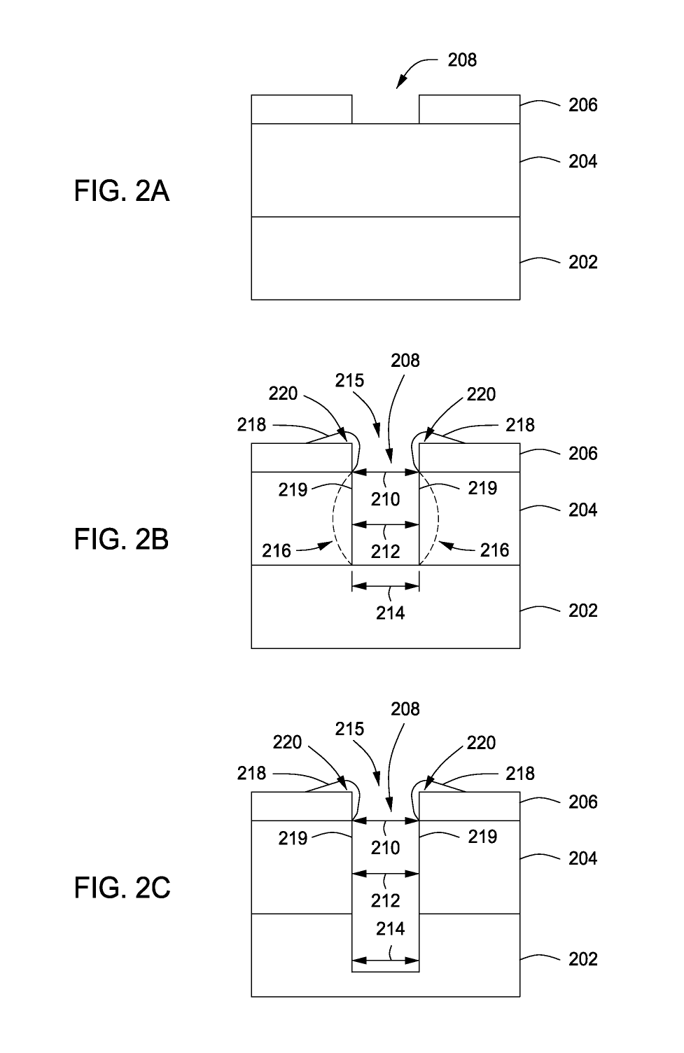

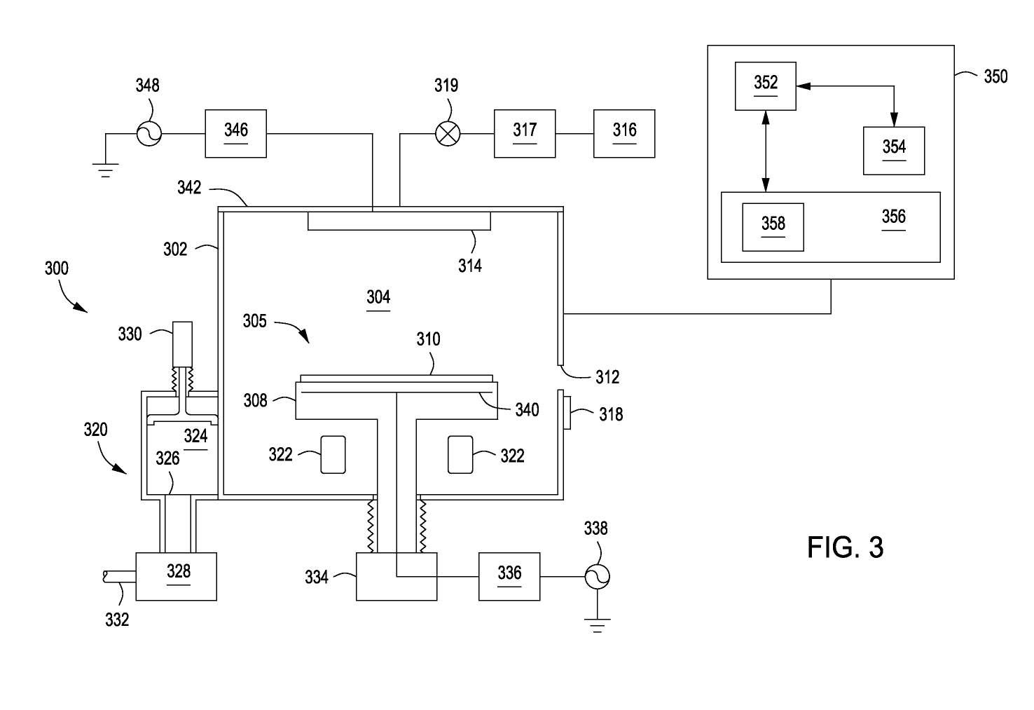

FIG. 1 is a flow diagram of a method for etching an oxide layer in accordance with some embodiments of the present invention. FIGS. 2A-C are illustrative cross-sectional views of a substrate during different stages of the processing sequence of FIG. 1 in accordance with some embodiments of the present invention. The inventive methods may be performed in any apparatus suitable for processing semiconductor substrates in accordance with embodiments of the present invention, such as the apparatus discussed below with respect to FIG. 3.

The method 100 generally begins at 102 where a substrate 202 having an oxide layer 204 disposed thereon is provided, as depicted in FIG. 2A. A patterned layer 206 may be disposed above the oxide layer 204 to define a pattern to be transferred into the oxide layer 204 via a subsequent etch process. It is contemplated that other layers may also be present on the substrate. The substrate 202 may be any suitable substrate, such as a doped or un-doped silicon substrate, a III-V compound substrate, a silicon germanium (SiGe) substrate, an epi-substrate, a silicon-on-insulator (SOI) substrate, a display substrate such as a liquid crystal display (LCD), a plasma display, an electro luminescence (EL) lamp display, a light emitting diode (LED) substrate, a solar cell array, solar panel, or the like. In some embodiments, the substrate 202 may be a semiconductor wafer, such as a 200 or 300 mm semiconductor wafer.

The patterned layer 206 may define one or more features 208 (e.g., a via, a trench, a dual damascene structure, or the like) to be etched into one or more underlying layers (e.g., the oxide layer 204) and/or the substrate 202. The patterned layer 206 may be any layer suitable to provide a template to form the one or more features 208, for example, such as a mask layer or hard mask layer, a photoresist layer, or the like. For example, in embodiments where the patterned layer 206 is a hard mask layer, the patterned layer 204 may comprise at least one of oxides, such as silicon dioxide (SiO₂), silicon oxynitride (SiON), or the like, or nitrides, such as titanium nitride (TiN), silicon nitride (SiN), or the like, silicides, such as titanium silicide (TiSi), nickel silicide (NiSi) or the like, or silicates, such as aluminum silicate (AISiO), zirconium silicate (ZrSiO), hafnium silicate (HfSiO), or the like. Alternatively, or in combination, in some embodiments, the patterned layer 206 may comprise an amorphous carbon, such as Advanced Patterning Film (APF), available from Applied Materials, Inc., located in Santa Clara, Calif., a tri-layer resist (e.g., a photoresist layer, a Si-rich anti-reflective coating (ARC) layer, and a carbon-rich ARC, or bottom ARC (BARC) layer), a spin-on hardmask (SOH), or the like. The patterned layer 206 may be formed by any suitable process. For example, in some embodiments, the patterned layer 206 may be formed via a patterned etch process. In some embodiments, for example where the patterned layer 206 will be utilized to define advanced or very small node devices (e.g., about 40 nm or smaller nodes, such as in memory applications such as Flash memory devices, DRAM, or the like), the patterned layer 206 may be formed via a spacer mask patterning technique, such as a self-aligned double patterning process (SADP).

The oxide layer 204 may comprise any oxide suitable for semiconductor fabrication. For example, in some embodiments, the oxide layer 204 may comprise a metal oxide, such as hafnium oxide (HfO₂), titanium oxide (TiO₂), or the like, a glass, such as phosphosilicate Glass (PSG), or the like, or silicon oxide (SiO₂), for example such as TEOS (tetraethooxysilane) silicon oxide (SiO₂), or a doped silicon oxide (SiO₂), such as carbon-doped silicon oxide (SiOC), silicon oxynitride (SiON), or the like. In addition, one or more additional layers (not shown) may also be disposed between the substrate 202 and the patterned layer 206. The one or more additional layers may comprise any type of layer suitable for semiconductor fabrication, for example, oxide layers, nitride layers, high or low K dielectric layers, conductive layers, or the like.

Next, at 104, a process gas comprising a polymer forming gas and an oxygen containing gas is provided. In some embodiments, the process gas may be provided at a total flow rate of about 100 sccm to about 1500 sccm at pressure range of 15 mTorr to 150 mTorr.

In some embodiments, the polymer forming gas may comprise a fluorine-containing gas, a fluorocarbon-containing gas or hydrofluorocarbon-containing gas as the primary reactive agent. For example, in embodiments where the process gas comprises a fluorine-containing gas, the fluorine-containing gas may comprise gases that can be dissociated to form fluorine radicals, such as NF₃, SF₆, or the like. In embodiments where the process gas comprises a fluorocarbon-containing gas such as CF₄, C₄F₆, C₄F₈, or the like, the fluorocarbon-containing gas may comprise gases that dissociate to form fluorine radicals and CFₓ (where x is a positive integer). In embodiments where the process gas comprises a hydrofluorocarbon-containing gas such as CH₂F₂, CH₄, CHF₃, or the like, the hydrofluorocarbon-containing gas may comprise gases that dissociate to form F radicals and CFₓ, as well as that provides hydrogen (H) that combines with the free fluorine to increase a C:F ratio (or C:H:F ratio).

In some embodiments, the ratio of C:F (or C:H:F) may facilitate control of one or more properties of the plasma (although the bias power supplied also influences this behavior). For example, the inventors have observed that as an amount of fluorine within the plasma increases, the plasma becomes more reactive, and thus less polymerizing as compared to a plasma with less fluorine. For example, if the ratio of C:F is low (e.g., 1:2 or lower, such as when using C₄F₆), the plasma can provide more passivation (e.g., can form more polymer) as compared to a plasma formed from a chemistry where the ratio is high (e.g., 1:4 or greater, such as when using C₄F₈). For C:H:F chemistries, the greater the C—H containing chemical bonding, the easier it is to form a C—H—F polymer passivation precursor.

The oxygen containing gas may comprise any oxygen containing gas, for example, oxygen (O₂), carbon monoxide (CO), or the like. The presence of the oxygen containing gas may facilitate a control over an amount of fluorine radicals produced during exposure of the substrate to the process gas, therefore facilitating control over an amount of etch and amount of polymer formed. Accordingly, a flow rate ratio of the polymer forming gas to the oxygen containing gas may be adjusted to obtain a desired etch to polymer formation ratio. For example, in some embodiments, the flow rate ratio of oxygen containing gas to polymer forming gas may be about 1:2 to about 3:4. In addition, the flow rate ratio of the oxygen containing gas to polymer forming gas may be continually adjusted to achieve a obtain a desired etch to polymer formation ratio (e.g., via pulsing one or both of the oxygen containing gas and polymer forming gas during the etch, as described below).

In some embodiments, a dilutant gas may optionally be provided with the process gas. The dilutant gas may be any inert gas, such as nitrogen (N₂), helium (He), argon (Ar), xenon (Xe), or the like. In some embodiments, the dilutant gas may be provided at a flow rate of about 100 to about 1500 sccm.

Next, at 106 a plasma may be optionally formed from the process gas. To form the plasma, the process gas may be ignited into a plasma by coupling some energy to the process gas within a process chamber (e.g., process chamber 300 described below) under suitable conditions to establish the plasma. In some embodiments, the energy coupled to the process gas may comprise up to about 3000 W of DC energy. Alternatively or in combination, in some embodiments, RF energy may be supplied at up to about 10,000 W at a frequency of about 2 MHz to about 162 MHz.

In addition to the above, additional process parameters may be utilized to ignite or maintain the plasma. For example, in some embodiments, the process chamber may be maintained at a pressure of about 4 to about 300 mTorr. In addition, in some embodiments, the process chamber may be maintained at a temperature of about 30 to about 90 degrees Celsius.

Next, at 108, the oxide layer 204 is etched while pulsing at least one of the polymer forming gas or the oxygen containing gas, as depicted in FIG. 2B. By etching the oxide layer 204 through the patterned layer 206, the one or more features 208 are etched into the oxide layer 204. The one or more features may have any dimensions suitable for the particular device being fabricated. For example, in some embodiments, the one or more features may have a top critical dimension 210 of about 30 to about 180 nm, and a bottom critical dimension 214 of up to about 100 nm.

Generally, to facilitate etching, an etchant species from the process gas (or plasma when present) reacts with a surface of the oxide layer 204 causing the oxide layer 204 material to form a gaseous state, thereby allowing it to be removed. Alternatively, or in combination, in embodiments where a plasma is formed (as described above) ions from the plasma may be accelerated towards the substrate 202, causing material to be ejected from the oxide layer 208, thereby etching the desired features into the oxide layer 208. In some embodiments, the ions may be directed toward the substrate 202 via a self bias formed on the substrate 202 resulting from the application of RF power to the process gas to form the plasma, as discussed above. Alternatively, or in combination, to facilitate directing the ions towards the substrate 202 an additional bias power may be provided to the substrate 202 via a substrate support disposed in a process chamber, for example, such as discussed below with respect to FIG. 3.

The inventors have observed that conventional oxide layer etching processes display poor etch selectivity and an imbalance with respect to an etch rate and polymer formation, which may result in a clogged feature opening 215, reduced etch rates for smaller features (Aspect Ratio Dependant Etch (ARDE)) and undesired profile shapes, for example, bowing of the feature sidewall 209 (shown in phantom at 216) or undesired critical dimensions (e.g., non-uniformities in the top critical dimension 210, bulk critical dimension 212 or bottom critical dimension 214) Accordingly, the inventors have discovered that by pulsing at least one of the polymer forming gas or the oxygen containing gas, a desired balance between polymer formation and etching may be achieved, allowing for improved control over etch selectivity, etch rate, improved control over the profile of the one or more features 208 and a minimization of feature bowing. For example, the inventors have observed that in embodiments where a chlorofluorocarbon gas is utilized to etch a dielectric layer, for example such as in a container application, etch selectivity may be improved by about 45%. Moreover, bowing may be improved by about 10-15%.

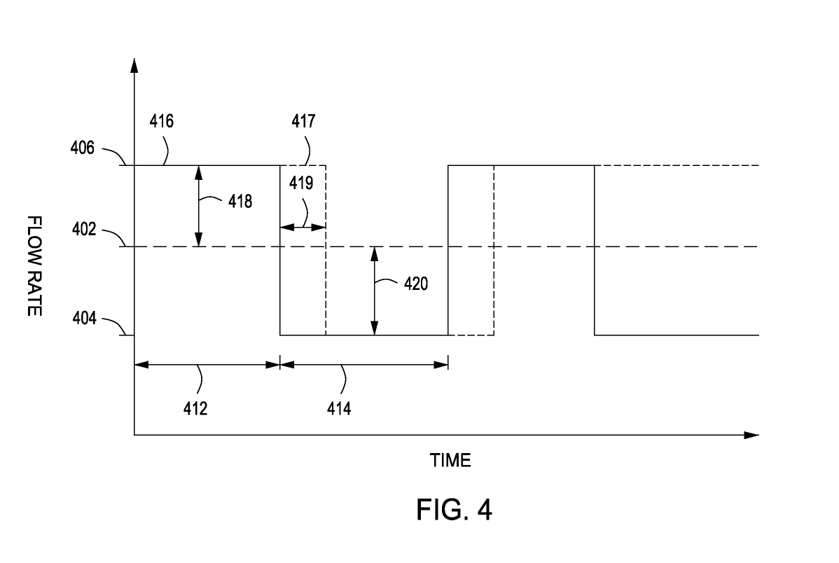

In embodiments where both the polymer forming gas and the oxygen containing gas are pulsed, the pulsing of each gas may be synchronized or, in some embodiments, unsynchronized (e.g., out of phase). In embodiments where the polymer forming gas and the oxygen containing gas are pulsed out of phase, the respective pulses of both the polymer forming gas and the oxygen containing gas may be phase shifted up to about 180 degrees with respect to one another (for example, such as shown by the first pulse diagram 416 and second pulse diagram 417 separated by a phase shift 419, as depicted in FIG. 4). Alternatively, in some embodiments, only one of the polymer forming gas or oxygen containing gas is pulsed while the non-pulsed gas is provided at a constant flow rate. For example, in some embodiments, the oxygen containing gas may be provided at a constant flow rate and the polymer forming gas may be pulsed. Alternatively, in some embodiments, the polymer gas may be provided at a constant flow and the oxygen containing gas may be pulsed.

The polymer forming gas and/or oxygen containing gas may be pulsed at any rate and at any magnitude suitable to achieve the desired balance between polymer formation and etching. For example, in some embodiments, each pulse of the polymer forming gas and/or oxygen containing gas may comprise providing the polymer forming gas and/or oxygen containing gas at a first flow rate 406 for a first period of time 412, then at a second flow rate 404 for a second period of time 414, for example, as depicted in FIG. 4. In some embodiments, the polymer forming gas and/or oxygen containing gas may be pulsed about an average flow rate 402 at a predetermined magnitude (such as magnitudes 418, 420 shown in FIG. 4). The polymer forming gas and the oxygen containing gas may be pulsed about the same average flow rate, or independent average flow rates. In such embodiments, the polymer forming gas and/or oxygen containing gas may be pulsed about the average flow rate 402 at a magnitude 418, 420 of up to 100%, or in some embodiments, up to 75%, or in some embodiments, up to 50%, or in some embodiments, up to 25% of the magnitude of the average flow rate 402. The average flow rate 402 may be any suitable flow rate, for example such as about 5 sccm to about 80 sccm As a non-limiting example, if the average flow rate of the polymer forming gas is about 55 sccm and the polymer forming gas is pulsed about the average flow rate at a magnitude of about 25 percent of the magnitude of the average flow rate, the first flow rate 406 would be about 68.75 sccm and the second flow rate would be about 44.0 sccm.

In embodiments where the polymer forming gas and/or oxygen containing gas are pulsed about the average flow rate 402 at an magnitude 418, 420 of about 100% of the magnitude of the average flow rate 402, each pulse cycle (i.e. the first period of time 412 and second period of time 414) may provide a period of time where the polymer forming gas and/or oxygen containing gas is supplied (on interval) followed by a period of time the polymer forming gas and/or oxygen containing gas is not supplied (off interval). In such embodiments, the “off” intervals separate successive “on” intervals and the “on” and “off” intervals define a controllable duty cycle. In some embodiments, the duty cycle may be between about 20 to about 50 percent. In some embodiments, each cycle period (i.e., the first period of time 412 and second period of time 414) may be greater than about 2 seconds, or in some embodiments less than about 6 seconds, or in some embodiments, less than about 5 seconds.

The first period of time 412 and the second period of time 414 may be any length of time suitable to achieve the desired balance between polymer formation and etching. The first period of time 412 and the second period of time 414 may be the same or they may be different. In some embodiments, the first period of time 412 and the second period of time 414 may be greater than about 0.5 seconds, or in some embodiments, about 1 to about 4 seconds. In some embodiments, the first period of time 412 and the second period of time 414 are equal. For example, in some embodiments, each of the first period of time 412 and the second period of time 414 may comprise about 1 second, or in some embodiments, about 2 seconds. Alternatively, in some embodiments, the first period of time 412 and the second period of time 414 may be different. For example, in some embodiments the first period of time 412 may be about 3 seconds, or in some embodiments, about 4 seconds, and the second period of time 414 may be about 1 second, or in some embodiments, about 2 seconds.

The inventors have discovered that by pulsing at least one of the polymer forming gas or the oxygen containing gas as described above, the etching process may be controlled via a balance of polymer generation and the presence of etchant species. For example, in embodiments where the oxide layer 204 comprises silicon oxide (SiO₂), a non-limiting example of a suitable process gas may comprise a polymer containing gas comprising carbon tetrafluoride (CE) and an oxygen containing gas comprising carbon monoxide (CO). In such embodiments, a plasma may be formed from the process gas. During the oxide layer 204 etch the polymer containing gas may be pulsed at an magnitude 418, 420 of about 50% about an average flow rate 402 of, for example, about 55 sccm. Each pulse cycle may comprise providing the polymer containing gas at a first flow rate 406 of about 82.5 sccm for a first period of time 418 of about 2 seconds followed by a second flow rate 404 of about 27.5 sccm for a second period of time 414 of about 2 seconds. The oxygen containing gas may be provided at a constant flow rate of about 40 to about 45 sccm.

During the first period of time 412, the increased amount of the polymer forming gas creates a fluorocarbon rich environment (and/or an oxygen deficient environment) which limits the amount of fluorine radicals and produces an abundance of fluorocarbon (CF), thereby allowing polymer generation to occur (e.g., a polymer 218 may be deposited atop a bevel 220 of the feature 208, as shown in FIG. 2B). During the second period of time 414, the decreased amount of the polymer forming gas creates an oxygen rich environment (and/or a fluorocarbon deficient environment) which limits the amount of fluorocarbon (CFₓ) and produces an abundance of free fluorine (F) radicals, thereby limiting polymer generation and allowing etching to occur.

In addition to the above, in embodiments where a plasma is formed from the process gas (as described above), the plasma may be pulsed to facilitate further control over the depth and/or width of the one or more features 208 during the etching process. For example, plasma may be pulsed via pulsing one or more of the source or bias power provided to ignite and/or maintain the plasma. In some embodiments, one or more of the source or bias power may be pulsed at a pulse frequency of up to about 0.5 Hz. In some embodiments, one or more of the source or bias power may be pulsed at a duty cycle of about 50 to about 80 percent. In some embodiments, both the source and bias power are pulsed to facilitate pulsing the plasma. In such embodiments, the source and bias power may be pulsed in synchronization, e.g., each signal has the same duty cycle and may be in phase or out of phase with respect to one another.

Alternatively, or in combination, in some embodiments, the pulsing condition of the plasma, (e.g., the duty cycle and/or the pulse frequency) may be varied to facilitate control over the one or more features 208 during the etching process. For example, in some embodiments the duty cycle of the power provided to plasma (bias and/or source power) may be varied to facilitate the plasma pulsing. In such embodiments, the plasma may be generated during successive “on” times, and ion energy of the plasma allowed to decay during successive “off” intervals. Selection of the duration of the on times and off times may facilitate control over the length of time where the plasma is generated and/or decayed.

In addition, in some embodiments, the length of time of the plasma is pulsed may be varied to further facilitate control over the over the depth or width of one or more features 208 during etching processes. For example, the plasma may be maintained in a continuous wave for a first period of time, followed by a period of time during which the plasma is pulsed. For example, in some embodiments, after ignition and stabilization of the plasma, as described above, the plasma may then be pulsed for a period of about 3 to about 10 seconds (e.g., one cycle). In addition, in some embodiments, plasma pulsing period may be followed by another period of time wherein the plasma is provided in a continuous wave. This continuous wave/plasma pulsing cycle may be sequentially performed any number of times suitable to achieve adequate etching of the one or more features 208.

Upon completion of etching the oxide layer 204 while pulsing at least one of the polymer forming gas or the oxygen containing gas at 108, the process generally ends and the substrate may continue to be processed as desired. For example, in some embodiments, additional etch processes may be performed to etch the feature 208 into the substrate 202, as depicted in FIG. 2C. In such embodiments, the subsequent etch processes may be performed similar to the etch process as described above. Although described above in the context of etching oxide layers, it is to be understood that the inventive methods described herein may be utilized to etch other materials such as nitrides, mask materials (e.g., amorphous carbon such as Advanced Patterning Film (APF), available from Applied Materials, Inc., located in Santa Clara, Calif., photoresist layers, antireflective coatings, or the like), or the like.

FIG. 3 depicts an apparatus 300 suitable for processing a substrate in accordance with some embodiments of the present invention. The apparatus 300 may comprise a controller 350 and a process chamber 302 having an exhaust system 320 for removing excess process gases, processing by-products, or the like, from the interior of the process chamber 305. Exemplary process chambers may include the DPS®, ENABLER®, ADVANTEDGE™, or other process chambers, available from Applied Materials, Inc. of Santa Clara, Calif. Other suitable process chambers may similarly be used.

The process chamber 302 has an inner volume 305 that may include a processing volume 304. The processing volume 304 may be defined, for example, between a substrate support pedestal 308 disposed within the process chamber 302 for supporting a substrate 310 thereupon during processing and one or more gas inlets, such as a showerhead 314 and/or nozzles provided at desired locations. In some embodiments, the substrate support pedestal 308 may include a mechanism that retains or supports the substrate 310 on the surface of the substrate support pedestal 308, such as an electrostatic chuck, a vacuum chuck, a substrate retaining clamp, or the like (not shown). In some embodiments, the substrate support pedestal 308 may include mechanisms for controlling the substrate temperature (such as heating and/or cooling devices, not shown) and/or for controlling the species flux and/or ion energy proximate the substrate surface.

For example, in some embodiments, the substrate support pedestal 308 may include an RF bias electrode 340. The RF bias electrode 340 may be coupled to one or more bias power sources (one bias power source 338 shown) through one or more respective matching networks (matching network 336 shown). The one or more bias power sources may be capable of producing up to 1200 W at a frequency of about 2 MHz, or about 13.56 MHz, or about 60 Mhz. In some embodiments, two bias power sources may be provided for coupling RF power through respective matching networks to the RF bias electrode 340 at respective frequencies of about 2 MHz and about 13.56 MHz. In some embodiments, three bias power sources may be provided for coupling RF power through respective matching networks to the RF bias electrode 340 at respective frequencies of about 2 MHz, about 13.56 MHz, and about 60 Mhz. The at least one bias power source may provide either continuous or pulsed power. In some embodiments, the bias power source alternatively may be a DC or pulsed DC source.

The substrate 310 may enter the process chamber 302 via an opening 312 in a wall of the process chamber 302. The opening 312 may be selectively sealed via a slit valve 318, or other mechanism for selectively providing access to the interior of the chamber through the opening 312. The substrate support pedestal 308 may be coupled to a lift mechanism 334 that may control the position of the substrate support pedestal 308 between a lower position (as shown) suitable for transferring substrates into and out of the chamber via the opening 312 and a selectable upper position suitable for processing. The process position may be selected to maximize process uniformity for a particular process. When in at least one of the elevated processing positions, the substrate support pedestal 308 may be disposed above the opening 312 to provide a symmetrical processing region.

The one or more gas inlets (e.g., the showerhead 314) may be coupled to a gas supply 316 for providing one or more process gases through a mass flow controller 317 into the processing volume 304 of the process chamber 302. In addition, one or more valves 319 may be provided to control the flow of the one or more process gases. The mass flow controller 317 and one or more valves 319 may be used individually, or in conjunction to provide the process gases at desired flow rates at a constant flow rate, or pulsed (as described above).

Although a showerhead 314 is shown in FIG. 3, additional or alternative gas inlets may be provided such as nozzles or inlets disposed in the ceiling or on the sidewalls of the process chamber 302 or at other locations suitable for providing gases as desired to the process chamber 302, such as the base of the process chamber, the periphery of the substrate support pedestal, or the like.

In some embodiments, the apparatus 300 may utilize capacitively coupled RF power for plasma processing, although the apparatus may also or alternatively use inductive coupling of RF power for plasma processing. For example, the process chamber 302 may have a ceiling 342 made from dielectric materials and a showerhead 314 that is at least partially conductive to provide an RF electrode (or a separate RF electrode may be provided). The showerhead 314 (or other RF electrode) may be coupled to one or more RF power sources (one RF power source 348 shown) through one or more respective matching networks (matching network 346 shown). The one or more plasma sources may be capable of producing up to about 3,000 W, or in some embodiments, up to about 5,000 W at a frequency of about 2 MHz and or about 13.56 MHz or high frequency, such as 27 MHz and/or 60 MHz. The exhaust system 320 generally includes a pumping plenum 324 and one or more conduits that couple the pumping plenum 324 to the inner volume 305 (and generally, the processing volume 304) of the process chamber 302.

A vacuum pump 328 may be coupled to the pumping plenum 324 via a pumping port 326 for pumping out the exhaust gases from the process chamber via one or more exhaust ports (two exhaust ports 322 shown) 302. The vacuum pump 328 may be fluidly coupled to an exhaust outlet 332 for routing the exhaust as required to appropriate exhaust handling equipment. A valve 330 (such as a gate valve, or the like) may be disposed in the pumping plenum 324 to facilitate control of the flow rate of the exhaust gases in combination with the operation of the vacuum pump 328. Although a z-motion gate valve is shown, any suitable, process compatible valve for controlling the flow of the exhaust may be utilized.

To facilitate control of the process chamber 302 as described above, the controller 350 may be one of any form of general-purpose computer processor that can be used in an industrial setting for controlling various chambers and sub-processors. The memory, or computer-readable medium, 356 of the CPU 352 may be one or more of readily available memory such as random access memory (RAM), read only memory (ROM), floppy disk, hard disk, or any other form of digital storage, local or remote. The support circuits 354 are coupled to the CPU 352 for supporting the processor in a conventional manner. These circuits include cache, power supplies, clock circuits, input/output circuitry and subsystems, and the like.

The inventive methods disclosed herein may generally be stored in the memory 356 as a software routine 358 that, when executed by the CPU 352, causes the process chamber 302 to perform processes of the present invention. The software routine 358 may also be stored and/or executed by a second CPU (not shown) that is remotely located from the hardware being controlled by the CPU 352. Some or all of the method of the present invention may also be performed in hardware. As such, the invention may be implemented in software and executed using a computer system, in hardware as, e.g., an application specific integrated circuit or other type of hardware implementation, or as a combination of software and hardware. The software routine 358 may be executed after the substrate 310 is positioned on the pedestal 308. The software routine 358, when executed by the CPU 352, transforms the general purpose computer into a specific purpose computer (controller) 350 that controls the chamber operation such that the methods disclosed herein are performed.

Thus, methods for etching an oxide layer disposed on a substrate through a patterned layer defining one or more features to be etched into the oxide layer have been provided herein. The inventive methods may advantageously provide an improved control over the critical dimensions of features formed in the oxide layer. The inventive process may further advantageously provide flexibility in control over the feature profile, etch rate, and etch selectivity with respect to the oxide layer and underlying layers of the substrate.

While the foregoing is directed to embodiments of the present invention, other and further embodiments of the invention may be devised without departing from the basic scope thereof.

1. A method for etching an oxide layer disposed on a substrate through a patterned layer defining one or more features to be etched into the oxide layer, the method comprising:
etching the oxide layer through the patterned layer using a process gas comprising a polymer forming gas and an oxygen containing gas to form the one or more features in the oxide layer; and
pulsing at least one of the polymer forming gas or the oxygen containing gas for at least a portion of etching the oxide layer to control a dimension of the one or more features.

2. The method of claim 1, wherein the polymer forming gas comprises a fluorine-containing gas, a fluorocarbon-containing gas, or hydrofluorocarbon-containing gas.

3. The method of claim 1, wherein the oxygen containing gas comprises carbon monoxide (CO) or oxygen (O₂).

4. The method of claim 1, wherein pulsing at least one of the polymer forming gas or the oxygen containing gas comprises providing the at least one of the polymer forming gas or the oxygen containing gas in a plurality of pulses, wherein each pulse comprises:
providing at least one of the polymer forming gas or the oxygen containing gas at a first flow rate for a first period of time; and
subsequently providing the at least one of the polymer forming gas or the oxygen containing gas at a second flow rate, different than the first flow rate, for a second period of time.

5. The method of claim 4, wherein the first flow rate and the second flow rate have an average flow rate of about 5 to about 80 sccm.

6. The method of claim 4, wherein the first period of time and the second period of time are about 0.5 seconds to about 4 seconds.

7. The method of claim 1, wherein the at least one of the polymer forming gas or the oxygen containing gas is pulsed at a duty cycle of about 20 to about 50 percent.

8. The method of claim 1, wherein one of the one polymer forming gas or the oxygen containing gas is pulsed and the other of the one polymer forming gas or the oxygen containing gas is provided at a constant flow rate.

9. The method of claim 1, wherein the oxide layer comprises a dielectric material.

10. The method of claim 1, wherein pulsing at least one of the polymer forming gas or the oxygen containing gas further comprises:
pulsing the polymer forming gas and the oxygen containing gas, wherein the polymer forming gas and the oxygen containing gas are pulsed out of phase with respect to each another.

11. The method of claim 1, wherein the one more features have a top critical dimension of about 30 to about 180 nm and a bottom critical dimension of up to about 100 nm.

12. The method of claim 1, wherein etching the oxide layer further comprises forming a plasma from the process gas by coupling at least one of a DC power or an RF power to the process gas to ignite the process gas to form the plasma.

13. The method of claim 12, further comprising:
coupling the RF power to the process gas to ignite the plasma; and
pulsing the RF power while etching the oxide layer.

14. The method of claim 12, wherein the DC power is provided at up to about 3000 W or the RF power is provided at up to about 10,000 W at a frequency of between about 2 MHz to about 500 MHz.

15. A computer readable medium having instructions stored thereon that, when executed, cause a method for etching an oxide layer disposed on a substrate through a patterned layer defining one or more features to be etched into the oxide layer to be performed in a process chamber, the method comprising:
etching the oxide layer through the patterned layer using a process gas comprising a polymer forming gas and an oxygen containing gas to form the one or more features in the oxide layer; and
pulsing at least one of the polymer forming gas or the oxygen containing gas for at least a portion of etching the oxide layer to control a dimension of the one or more features.

16. The computer readable medium of claim 15, wherein pulsing at least one of the polymer forming gas or the oxygen containing gas comprises providing the at least one of the polymer forming gas or the oxygen containing gas in a plurality of pulses, wherein each pulse comprises:
providing at least one of the polymer forming gas or the oxygen containing gas at a first flow rate for a first period of time; and
subsequently providing the at least one of the polymer forming gas or the oxygen containing gas at a second flow rate, different than the first flow rate, for a second period of time.

17. The computer readable medium of claim 15, wherein the at least one of the polymer forming gas or the oxygen containing gas is pulsed at a duty cycle of about 20 to about 50 percent.

18. The computer readable medium of claim 15, wherein pulsing at least one of the polymer forming gas or the oxygen containing gas further comprises:
pulsing the polymer forming gas and the oxygen containing gas, wherein the polymer forming gas and the oxygen containing gas are pulsed out of phase with respect to each another.

19. The computer readable medium of claim 15, wherein the method further comprises:
coupling the RF power to the process gas to ignite the plasma; and
pulsing the RF power while etching the oxide layer.

20. The computer readable medium of claim 15, wherein etching the oxide layer further comprises forming a plasma from the process gas by coupling at least one of a DC power or an RF power to the process gas to ignite the process gas to form the plasma.
